(19) United States
(12) Patent Application Publication
(10) Pub. No.: US 2024/0047940 A1
(43) Pub. Date: Feb. 8, 2024

(54) PULSED LASER DIODE DRIVER CURRENT MEASUREMENT CIRCUIT

(71) Applicant: Silanna Asia Pte Ltd, Singapore (SG)

(72) Inventors: Joseph H. Colles, Bonsall, CA (US); Steven E. Rosenbaum, San Diego, CA (US); Stuart B. Molin, Carlsbad, CA (US)

(73) Assignee: Silanna Asia Pte Ltd, Singapore (SG)

(21) Appl. No.: 18/360,215

(22) Filed: Jul. 27, 2023

Related U.S. Application Data
(60) Provisional application No. 63/370,271, filed on Aug. 3, 2022.

(51) Int. Cl. H01S 5/042

(52) U.S. Cl. CPC H01S 5/0428; H01S 5/0425

(57) ABSTRACT

A pulsed laser diode driver includes a laser diode switch and a bypass switch to control a current flow through an inductor to produce a high-current pulse through a laser diode, the high-current pulse corresponding to a peak current of a resonant waveform developed at an anode of the laser diode. A current pulse measurement circuit receives a sense voltage developed at a sense resistance and generates, based on the sense voltage, a current sense signal that corresponds to the peak current amplitude of the high-current pulse through the laser diode.

### RELATED APPLICATIONS

This application claims priority to U.S. Provisional Application No. 63/370,271, filed Aug. 3, 2022, all of which is incorporated by reference for all purposes.

### BACKGROUND

Laser-based ranging systems, such as Lidar, often use a pulsed laser diode driver circuit to generate a short, high-current pulse, which is passed through a laser diode to emit a corresponding pulse of laser light. Reflected pulses of laser light are received by the Lidar system and used to determine a distance between the Lidar system and the point of reflection. The spatial resolution of Lidar systems is determined in part by the width of the pulse of laser light. Thus, it is usually desirable to generate a pulse of light having a width of about 5 ns or less. However, parasitic inductances of the pulsed laser diode driver circuit and the laser diode typically must be overcome to achieve the desired short pulse width. For example, many laser diodes have at least one bond wire which can contribute 1 nH of inductance, thereby limiting a slew rate of the current pulse unless there is very high voltage. Thus, some conventional pulsed laser diode driver circuits use a high source voltage, often greater than 40V to 100V, to achieve the desired pulse width.

The amplitude of light output from a laser diode is proportional to, and is typically controlled by, a peak amplitude of the high-current pulse through the laser diode. However, because power efficiency is often an important design parameter, measuring the amplitude of the high-current pulse using a discrete current sense resistor is typically not acceptable. Additionally, because the current pulse typically has a width of 5 ns or less, current measurement is a challenging design issue to overcome. Conventionally, current measurements of such narrow pulses are achieved using high-speed comparators or switches to determine a peak value of the current pulse or a peak voltage across a resistive sensing element.

### SUMMARY

In some embodiments, a pulsed laser diode driver includes a first inductor having a first terminal and a second terminal, the first terminal of the first inductor being configured to receive a first source voltage that is based on a DC input voltage. A first source capacitor has a first terminal directly electrically connected to the first terminal of the first inductor to provide the first source voltage, and a second terminal electrically coupled to ground. A first bypass switch has a drain node that is directly electrically connected to the second terminal of the first inductor and a source node that is directly electrically connected to ground. A first bypass capacitor has a first terminal directly electrically connected to the drain node of the first bypass switch. A first laser diode has an anode and a cathode. The anode of the first laser diode is directly electrically connected to the second terminal of the first inductor and to the drain node of the first bypass switch. A laser diode switch has a drain node that is directly electrically connected to the cathode of the first laser diode and a source node that is directly electrically connected to ground. A current pulse measurement circuit is configured to receive a sense voltage developed at a sense resistance and to generate, based on the sense voltage, a current sense signal that corresponds to a peak current amplitude of a high-current pulse through the first laser diode. The laser diode switch and the first bypass switch are configured to control a current flow through the first inductor to produce the high-current pulse through the first laser diode, the high-current pulse corresponding to a peak current of a resonant waveform developed at the anode of the first laser diode.

In some embodiments, a pulsed laser diode driver includes a laser diode having an anode and a cathode. A laser diode switch has a drain node that is directly electrically connected to the cathode of the laser diode and a source node that is directly electrically connected to ground. A current pulse measurement circuit is configured to receive a sense voltage, developed at a sense resistance, that is based on a high-current pulse through the laser diode, and to generate, based on the sense voltage, a current sense signal that corresponds to a peak current amplitude of the high-current pulse. A resistance of the sense resistance corresponds to a drain-source on-resistance of a first portion of fingers of the laser diode switch.

In some embodiments, a current pulse measurement circuit includes a voltage offset circuit to generate an offset voltage. A sample and hold circuit receives i) a sense voltage developed at a sense resistance by a high-current pulse, and ii) the offset voltage, and generates a sampled signal therefrom. A first voltage amplifier circuit receives the sampled signal and generates a first scaled sampled signal therefrom. A second voltage amplifier circuit receives the offset voltage and generates a scaled offset voltage signal therefrom. A voltage adder circuit adds the first scaled sampled signal and the scaled offset voltage signal and generates a second scaled sampled signal therefrom. A current mirror circuit receives the second scaled sampled signal and generates a current sense signal therefrom, the current sense signal corresponding to a peak current amplitude of the high-current pulse.

### BRIEF DESCRIPTION OF THE DRAWINGS

FIG. 1 is a simplified circuit schematic of a pulsed laser diode driver of a first general topology, in accordance with some embodiments.

FIGS. 2A-2D show simplified plots of signals related to operation of the pulsed laser diode driver shown in FIG. 1, in accordance with some embodiments.

FIG. 3 is a portion of an example switching sequence for operation of the pulsed laser diode driver shown in FIG. 1, in accordance with some embodiments.

FIGS. 4-5 show simplified plots of signals related to operation of the pulsed laser diode driver shown in FIG. 1, in accordance with some embodiments.

FIG. 6 is a simplified circuit schematic of the current pulse measurement circuit shown in FIG. 1, in accordance with some embodiments.

FIG. 7 is a simplified circuit schematic of the sample and hold circuit of the current pulse measurement circuit shown in FIG. 6, in accordance with some embodiments.

FIGS. 8-10 show simplified plots of signals related to the operation of the current pulse measurement circuit in FIG. 6, in accordance with some embodiments.

FIG. 11 is a simplified circuit schematic of the current mirror circuit of the current pulse measurement circuit shown in FIG. 6, in accordance with some embodiments.

FIG. 12 is a simplified circuit schematic of a pulsed laser diode driver of a second general topology, in accordance with some embodiments.

### DETAILED DESCRIPTION

In accordance with some embodiments, pulsed laser diode driver circuits disclosed herein (“pulsed laser diode drivers”), generate high-current (e.g., 40 Amp) ultra-short pulses (e.g., 1-5 ns) to emit a laser pulse from a laser diode using a tunable resonant circuit, as compared to conventional solutions that rely on fixed, and often unavoidable, parasitic capacitances and inductances of a circuit. The tunable resonant circuit provides easily tunable parameters which control a pulse width, a peak current, a charge time, a recovery time, a decay time, and other tunable parameters of the pulsed laser diode driver. Embodiments of a switching sequence to drive the pulsed laser diode drivers disclosed herein are operable to generate a resonant waveform at an anode of the laser diode to produce the high-current pulse through the laser diode, a voltage level of the resonant waveform being advantageously sufficient to support the high-current pulse and not of a voltage level that exceeds the voltage required to generate the high-current pulse.

Thus, embodiments of such pulsed laser diode drivers can advantageously generate the high-current pulses using a low input voltage (e.g., 6V, 9V, 15V, etc.) and can thereby use Silicon-based switches, rather than GaN-based switches which are used by many conventional solutions. Any of the pulsed laser diode drivers disclosed herein can therefore be integrated into a single semiconductor die. Embodiments of pulsed laser diode drivers disclosed herein advantageously use a discrete inductor (e.g., a through-hole or surface-mounted component) intentionally added to the pulsed laser diode driver to generate a resonant waveform rather than relying on parasitic inductances (e.g., of the laser diode, of bond wires, or inter-circuit connections) of the pulsed laser diode driver. As a result, embodiments of the laser drivers disclosed herein are easily tunable and have a reproducible architecture. By contrast, conventional pulsed laser diode drivers often use a variety of techniques to overcome the effects of parasitic inductances of the pulsed laser diode driver and of the laser diode itself and therefore teach away from intentionally adding yet additional inductance to the pulsed laser diode driver. In addition to such intentionally added inductors, the pulsed laser diode drivers disclosed herein advantageously include a bypass capacitor that may be used by a designer to easily tune a desired pulse width emitted by the laser diode, as compared to conventional solutions which only have a source capacitor, or that only consider non-tunable parasitic capacitances of the pulsed laser diode driver. Once again, such conventional solutions teach away from adding yet additional capacitance to the pulsed laser diode driver. Because conventional solutions rely on parasitic capacitances and inductances of the conventional laser driver, modifying parameters, such as a pulse width, might require a redesign or re-layout of the conventional solution. By comparison, parameters, such as a pulse width, of the pulsed laser diode drivers disclosed herein can be tuned by simply changing a component value.

Multi-channel laser diodes are conventionally produced on a single monolithic substrate housed in a laser diode package. Conventionally, a single pin of the laser diode package is connected to all of the laser diode cathodes as a group (i.e., “common cathode”), whereas each laser diode anode is individually connected to a respective pin of the laser diode package. Pulsing each laser diode independently conventionally requires a switch in the laser diode anode current path to select which laser diode fires. However, an N-type switch conventionally requires a bootstrap circuit to level-shift a gate drive of that switch when the laser diode current path is enabled. Such bootstrap circuitry adds complexity and cost to a pulsed laser diode driver design. Thus, disclosed herein are embodiments of a multi-channel pulsed laser diode driver circuit for independently driving laser diodes of a common cathode multi-channel laser diode package advantageously using N-type switches without any bootstrap circuitry.

Lidar systems use laser diode drivers which generate very narrow, high-current pulses. The light output of a laser diode is proportional to the peak current pulse. Typically, the light output is controlled by changing the current. Since power efficiency is an important parameter, a discrete current sense resistor is often not acceptable. Thus, as disclosed herein, in some embodiments a current pulse measurement circuit advantageously uses a drain-source resistance (RDSon) of the same switch that is used to control laser diode pulse emission as a sense resistance. The current pulse measurement circuit additionally does not rely on high-speed comparators to determine a peak value of the current pulse or a peak voltage across the sense resistance, thereby reducing design cost and complexity as compared to current pulse measurement circuits that use high-speed comparators. Still additionally, the current pulse measurement circuit disclosed herein advantageously compensates for parametric changes of the RDSon of the switch due to temperature changes and/or voltage changes at nodes of the switch.

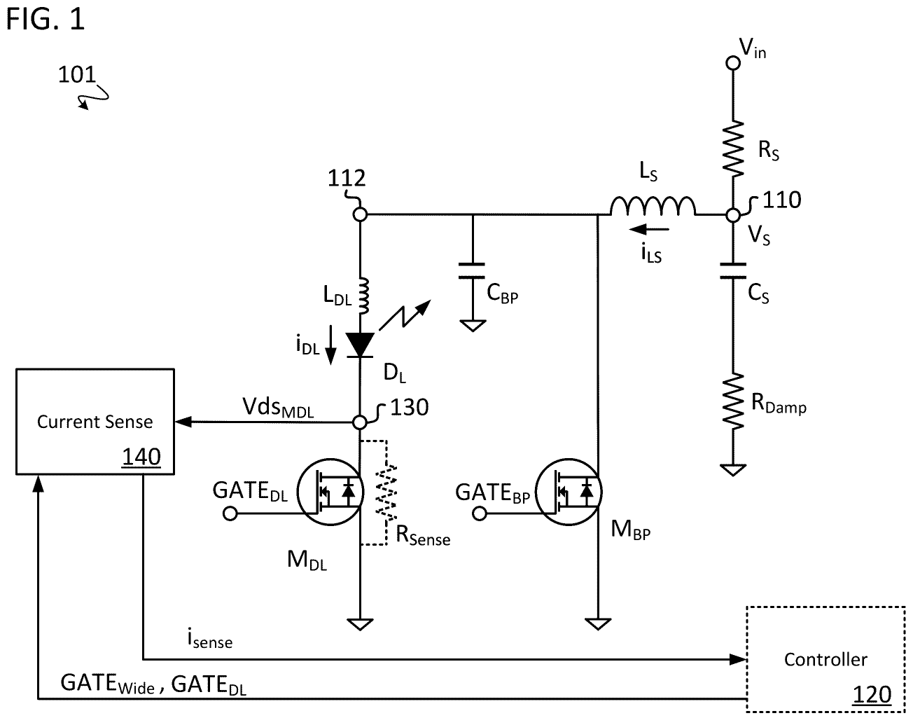

FIG. 1 is a simplified circuit schematic of a pulsed laser diode driver 101 of a first general topology to drive a laser diode using a low-side switch, in accordance with some embodiments. The pulsed laser diode driver generally includes a source resistor R_{S}, a source capacitor C_{S} (i.e., a physical component that is not representative of a parasitic capacitance of another component), a damping resistor R_{Damp}, an inductor Ls (i.e., a physical component that is not representative of a parasitic inductance of another component), a bypass capacitor C_{BP} (i.e., a physical component that is not representative of a parasitic capacitance of another component), a laser diode D_{L}, a bypass switch M_{BP}, a laser diode switch M_{DL}, a current sense resistance Rₛₑₙₛₑ, and a current pulse measurement circuit (current sense) 140. The current sense resistance Rₛₑₙₛₑ may be a discrete resistor or may be the drain-source on-resistance (RDSon) of a first portion m of fingers of the laser diode switch M_{DL}.

The laser diode switch M_{DL} is configured as a low-side switch. Also shown is a controller 120, nodes 110, 112, 130, a parasitic inductance L_{DL} of the laser diode D_{L}, a DC input voltage Vᵢₙ, a source voltage V_{S} at the source capacitor C_{S}, a current i_{LS} through the inductor L_{S}, a current i_{DL} through the laser diode D_{L}, a bypass switch gate driver signal GATE_{BP}, a laser diode switch gate driver signal GATE_{DL}, a wide gating signal GATE_{Wide} generated by the controller 120, and a current sense signal iₛₑₙₛₑ signal generated by the current pulse measurement circuit 140.

In the embodiment shown, a first terminal of the source resistor R_{S} is configured to be directly electrically connected to the DC input voltage Vᵢₙ. In other embodiments, the source resistor R_{S} is replaced with one or more switches (not shown) which may be used to rapidly charge the source capacitor C_{S}. A first terminal of the source capacitor C_{S} is directly electrically connected to a second terminal of the source resistor R_{S}, and a second terminal of the source capacitor C_{S} is directly electrically connected to a first terminal of the damping resistor R_{Damp}. A second terminal of the damping resistor R_{Damp} is directly electrically connected to a bias voltage node such as ground. Thus, the second terminal of the source capacitor C_{S} is electrically coupled to the bias voltage node. A first terminal of the inductor L_{S} is directly electrically connected to the second terminal of the source resistor R_{S} and to the first terminal of the source capacitor C_{S}. A drain node of the bypass switch M_{BP} is directly electrically connected to a second terminal of the inductor L_{S}, and a source node of the bypass switch M_{BP} is directly electrically connected to the bias voltage node. An anode of the laser diode D_{L} is directly electrically connected to the second terminal of the inductor L_{S}, and a cathode of the laser diode D_{L} is directly electrically connected to a drain node of the laser diode switch M_{DL}. A source node of the laser diode switch M_{DL} is directly electrically connected to the bias voltage node.

The bypass switch M_{BP} is configured to receive the bypass switch gate driver signal GATE_{BP} at a gate node, the bypass switch gate driver signal GATE_{BP} being operable to turn the bypass switch M_{BP} on or off based on a voltage level of the bypass switch gate driver signal GATE_{BP}. Similarly, the laser diode switch M_{DL} is configured to receive the laser diode switch gate driver signal GATE_{DL} at a gate node, the laser diode switch gate driver signal GATE_{DL} being operable to turn the laser diode switch M_{DL} on or off based on a voltage level of the laser diode switch gate driver signal GATE_{DL}. In some embodiments, the pulsed laser diode driver circuits disclosed herein include one or more bootstrap circuits or other level-shifting circuits to drive one or more high-side switches. Either or both of the bypass switch M_{BP} and the laser diode switch M_{DL} can be implemented as N-type switches or P-type switches. In some embodiments, the bypass switch M_{BP} and the laser diode switch M_{DL} are implemented as Silicon-based or Silicon-Carbide-based field-effect transistors (FETs). In other embodiments, the bypass switch M_{BP} and/or the laser diode switch M_{DL} are implemented as GAN FETs. Two or more components described herein as having terminals that are directly electrically connected have a DC current path between the respective terminals of the two or more components. For example, a first and second component are not directly electrically connected via a capacitor or inductor connected in series between the first component and the second component.

As shown in the simplified circuit schematic of the pulsed laser diode driver 101 of FIG. 1, in some embodiments a first terminal of the bypass capacitor C_{BP} is directly electrically connected to the second terminal of the inductor L_{S} and to the anode of the laser diode D_{L}. In such embodiments, a second terminal of the bypass capacitor C_{BP} is directly electrically connected to the bias voltage node.

In some embodiments, the pulsed laser diode driver 101 is configured to receive the DC input voltage Vᵢₙ having a voltage range from about 10V to 20V, which is advantageously lower than an input voltage used by many conventional pulsed laser diode drivers. The inductor L_{S} is a physical component added to the pulsed laser diode driver 101 (i.e., as opposed to a representation of a parasitic inductance caused by components or interconnections such as bond wires). Similarly, the bypass capacitor C_{BP} is a physical component added to the pulsed laser diode driver 101 (i.e., as opposed to a representation of a parasitic capacitance). One advantage of using physical inductor and capacitor components rather than using parasitic inductances is that values of the inductor L_{S} and the bypass capacitor C_{BP} can be easily modified by a designer or even an end-user. By comparison, conventional designs that rely on parasitic reactances may require re-design and/or re-layout to change an operating parameter.

As disclosed herein, values of the DC input voltage Vᵢₙ, the inductance of the inductor L_{S}, the capacitance of the source capacitor C_{S}, the resistance of the damping resistor R_{Damp}, and the capacitance of the bypass capacitor C_{BP} can advantageously be selected (“tuned”) to achieve a desired operation of the pulsed laser diode driver 101 (e.g., a charge time, a pulse width, a pulse voltage, a pulse current). For example, a pulse width of the current i_{DL} flowing through the laser diode D_{L} can be tuned by adjusting the capacitance value of the bypass capacitor C_{BP}. A peak current level of the pulse of current i_{DL} flowing through the laser diode D_{L} can be tuned by adjusting the source voltage V_{S} on the supply capacitor C_{S}. A capacitance value of the source capacitor C_{S} can be tuned to adjust a timing delay of the current pulse and an upper range of the current i_{DL} through the laser diode D_{L}. Resistance values of the damping resistor R_{Damp} are dependent on the capacitance value of the supply capacitor C_{S} and can be tuned within a range of values such that at a lower resistance, a lower frequency resonance of the pulsed laser diode drivers disclosed herein is underdamped (e.g., at about R_{Damp}=0.1 Ohms), or is critically damped (e.g., at about R_{Damp}=0.4 Ohms). The damping resistor R_{Damp} is operable to prevent current of the generated resonant waveform from becoming negative which could thereby enable a body diode of the bypass switch M_{BP} or the laser diode switch M_{DL}. Although a resulting maximum current level of the current i_{DL} through the laser diode D_{L} is lower for the critically damped case, the current level can be easily adjusted by raising the voltage level of the DC input voltage Vᵢₙ. In other embodiments, the damping resistor R_{Damp} is removed entirely from the design (i.e., the second terminal of the source capacitor C_{S} is directly electrically connected to the bias voltage node). In yet other embodiments, the resistance value of the damping resistor R_{Damp} is set to zero Ohms.

In some embodiments, the DC input voltage Vᵢₙ is about 15 V, the inductance of the inductor L_{S} is about 6 nH, the capacitance of the source capacitor C_{S} is about 100 nF, the resistance of the damping resistor R_{Damp} is about 0.1 Ohms, and the capacitance of the bypass capacitor C_{BP} is about 1 nF. In some embodiments, a voltage at the first terminal of the damping resistor R_{Damp} is received by the controller 120 to provide an indication of a current flow through the damping resistor R_{Damp}.

In some or all of the embodiments disclosed herein, to produce around a 40A high-current pulse through the laser diode (or laser diodes) D_{L}, the DC input voltage Vᵢₙ may range from 10-15 volts. In some such embodiments, the inductance of inductor L_{S} may range from 5-10 nH, the value of which determines the amount of flux delay to produce the required current. In some such embodiments, the inductance of the inductor L_{S} is selected to be an order of magnitude greater than a parasitic inductance of a printed circuit board (PCB) in which the pulsed laser diode driver is implemented. In some embodiments, the resistance of the damping resistor R_{S} ranges from 100-200 mOhms. A capacitance of the bypass capacitor C_{BP} determines the pulse width of the high-current pulse through the laser diode(s) D_{L}, and in some embodiments ranges in capacitance from 1-5 nF. In some such embodiments, a capacitance of the supply capacitor C_{S} ranges from 25-100 nF depending on a peak current of the high-current pulse through the laser diode(s) D_{L} that is required or desired. The smaller the supply capacitor C_{S}, the higher the DC input voltage Vᵢₙ is needed to get the required or desired peak current of the high-current pulse through the laser diode(s) D_{L}. In some such embodiments, a smallest capacitance value of the supply capacitor C_{S} that can still deliver the needed or desired peak current of the high-current pulse through the laser diode(s) D_{L} is selected because all the remaining energy after the high-current pulse is shunted to ground and is wasted, thereby lowering a power efficiency of the pulsed laser diode driver.

The controller 120 may be integrated with any embodiment of the pulsed laser diode drivers disclosed herein, or it may be a circuit or module that is external to any embodiment of the pulsed laser diode drivers disclosed herein. The controller 120 is operable to generate one or more gate drive signals having a voltage level that is sufficient to control one or more laser diode switches M_{DL} and one or more bypass switches M_{BP}. Additionally, the controller 120 is operable to sense a voltage and/or current at any of the nodes 110, 112, 130 and at nodes that are similar to, or the same as, the nodes 110, 112, 130 as described herein, or at still other nodes of the pulsed laser diode drivers disclosed herein. For example, the controller 120 is operable to provide gating signals GATE_{Wide} and GATE_{DL} to the current pulse measurement circuit 140 and to receive a current sense signal iₛₑₙₛₑ therefrom. The current sense signal iₛₑₙₛₑ is a signal that corresponds to a peak current amplitude value of the ultra-fast high current pulse i_{DL} which causes the laser diode D_{L} to emit a laser pulse. In some embodiments, the current sense signal iₛₑₙₛₑ is a scaled value that corresponds to a peak current amplitude of the ultra-fast high current pulse i_{DL}, the scalar relationship being determined during design of the current pulse measurement circuit 140 and based on desired, or required, design parameters. For example, in some embodiments, the scalar relationship is designed such that each volt developed across an external resistor by the current sense signal iₛₑₙₛₑ corresponds to one Amp of current through the current sense resistance Rₛₑₙₛₑ.

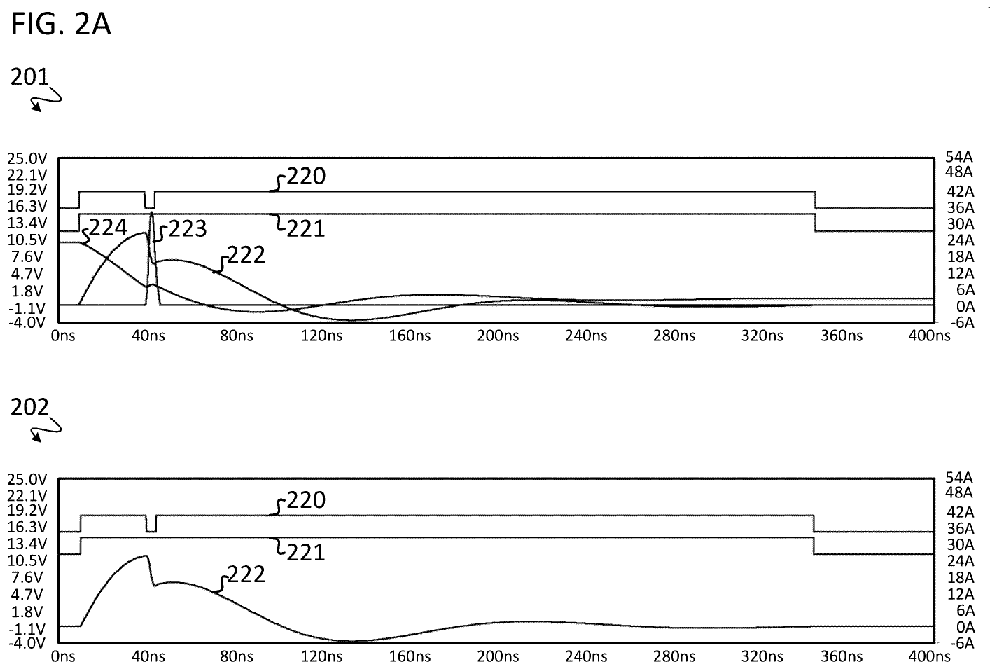

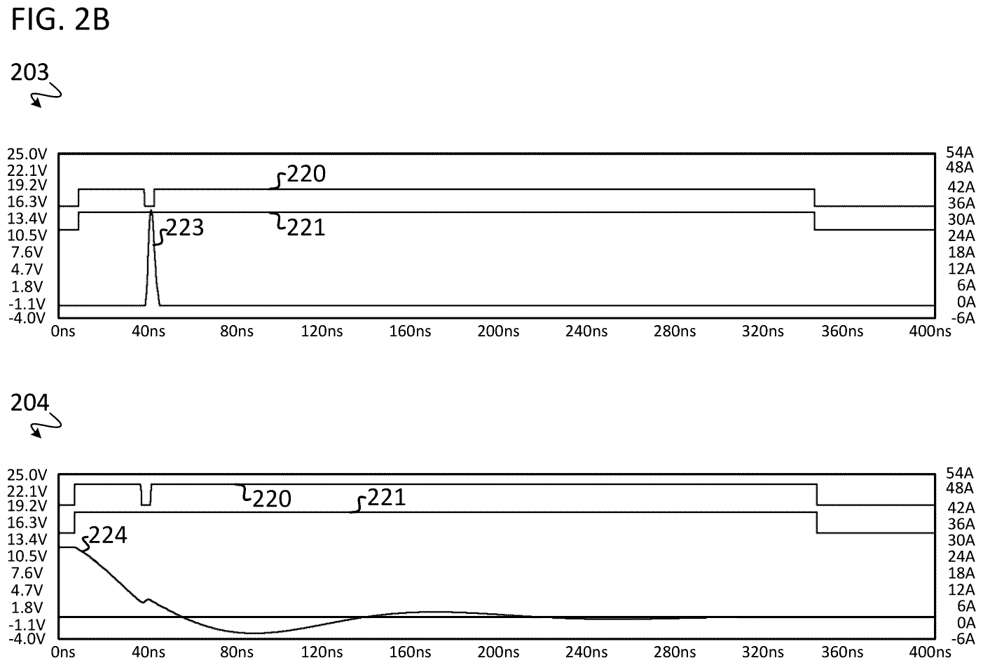

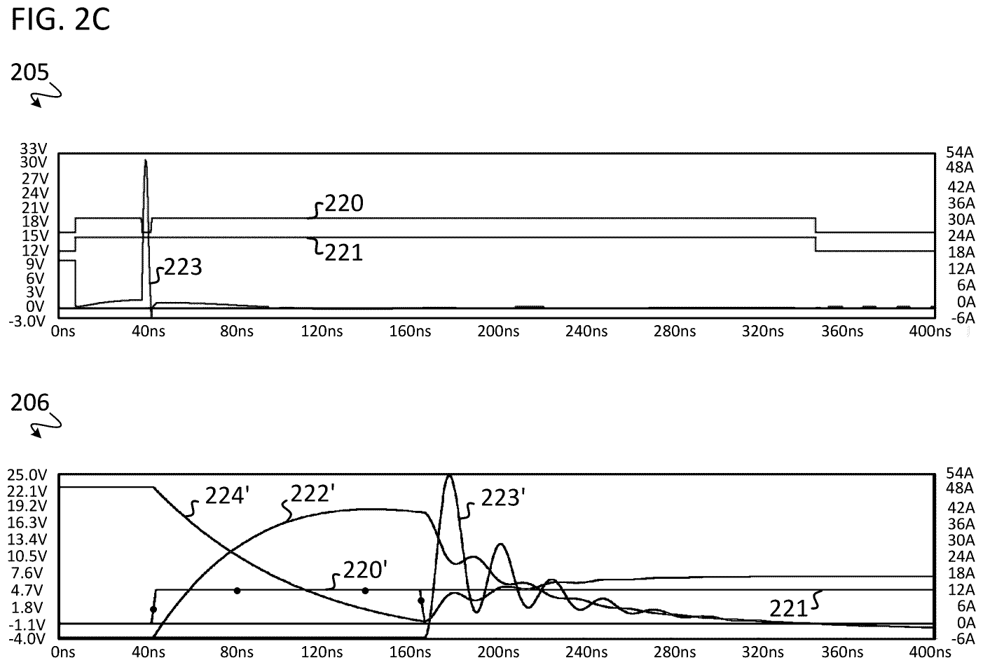

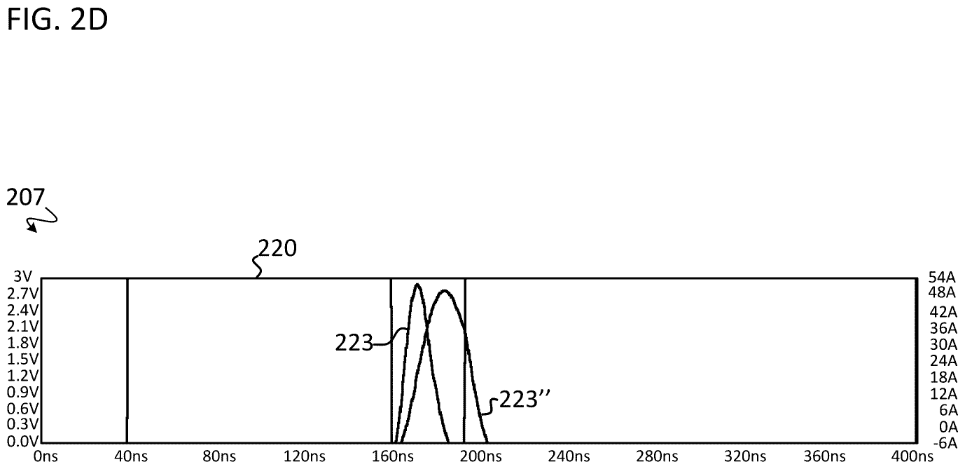

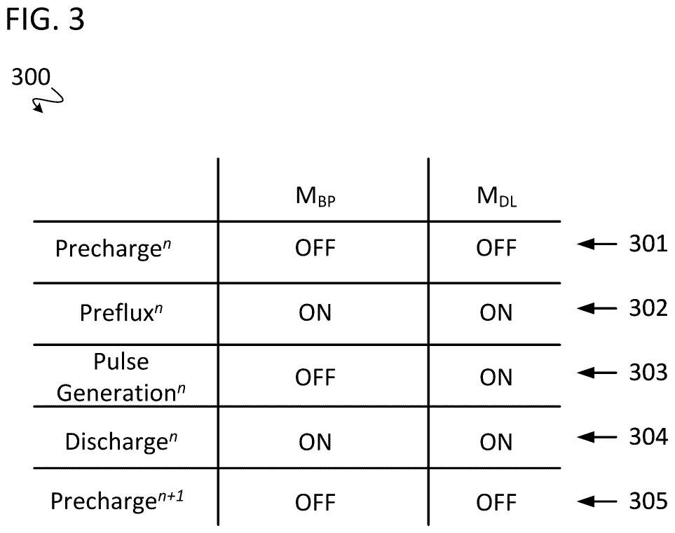

The controller 120 may include one or more timing circuits, look-up tables, processors, memory, or other modules to control the pulsed laser diode drivers disclosed herein. Operation of the pulsed laser diode driver 101 is explained in detail with respect to simplified plots 201-207 of FIGS. 2A-D and an example switching sequence 300 is shown in FIG. 3.

FIGS. 2A-2D show simplified plots 201-207 of signals related to operation of the pulsed laser diode driver 101 shown in FIG. 1, in accordance with some embodiments. The simplified plot 201 illustrates a voltage plot of the bypass switch gate driver signal GATE_{BP} 220, a voltage plot of the laser diode switch gate driver signal GATE_{DL} 221, a current plot of the current i_{LS} through the inductor L_{S} 222, a current plot of the high-current pulse i_{DL} through the laser diode D_{L} 223, and a voltage plot of the source voltage V_{S} 224 at the source capacitor C_{S}, all over the same duration of time. Details of these signals are described below. The voltage plots of the bypass switch gate driver signal GATE_{BP} 220 and the laser diode switch gate driver signal GATE_{DL} 221 have been level-shifted for readability, but are, in actuality, low-voltage inputs. Additionally, the voltage plots of the bypass switch gate driver signal GATE_{BP} 220 and the laser diode switch gate driver signal GATE_{DL} 221 assume that the laser diode switch M_{DL} and the bypass switch M_{BP} are NFET devices.

Upon receiving (e.g., from the controller 120) an asserted level of the bypass switch gate driver signal GATE_{BP} 220 at the gate node of the bypass switch M_{BP}, the bypass switch M_{BP} is enabled (i.e., transitioned to an ON-state). Similarly, upon receiving (e.g., from the controller 120) an asserted level of the laser diode switch gate driver signal GATE_{DL} 221 at the gate node of the laser diode switch M_{DL}, the laser diode switch M_{DL} is enabled. As highlighted in the plot 202, when the bypass switch M_{BP} is enabled, the rising current i_{LS} 222 begins to flow through the inductor L_{S}, thereby building magnetic flux at the inductor L_{S}. When the current i_{LS} 222 has reached a desired level (e.g., as determined by the controller 120 using sensed current, voltage, a timer circuit, or as determined by design constraints), a de-asserted level of the bypass switch gate driver signal GATE_{BP} 220 is received (e.g., from the controller 120) at the gate node of the bypass switch M_{BP}, thereby disabling the bypass switch M_{BP} (i.e., transitioned to an OFF-state). As highlighted in the plot 203, when the bypass switch M_{BP} is disabled, the current i_{LS} 222 which has built up through the inductor L_{S}, having no other current path, is redirected through the laser diode D_{L}, causing a short (e.g., 1 ns-5 ns), high-current (e.g., >30 A) pulse to flow through the laser diode D_{L}, thereby causing the laser diode D_{L} to emit a pulse of laser light. Because energy in the form of flux has been stored at the inductor L_{S}, the high-current pulse i_{DL} that flows through the laser diode D_{L} can be significantly greater than the current i_{LS} that flows through the inductor L_{S}. Values of the reactive components of the laser diode drivers disclosed herein can be advantageously selected to generate a desired current amplitude of the high-current pulse i_{DL}.

After emission from the laser diode D_{L}, the bypass switch M_{BP} is reenabled by an asserted level of the bypass switch gate driver signal GATE_{BP} 220, and the laser diode switch M_{DL} is maintained in an enabled state by an asserted level of the laser diode switch gate driver signal GATE_{DL} 221. As highlighted in the plot 204, the bypass switch M_{BP} and the laser diode switch M_{DL} are both advantageously maintained in the enabled state as the source voltage V_{S} 224 stored at the source capacitor C_{S} is discharged. As highlighted in the plot 205, while the bypass switch M_{BP} and the laser diode switch M_{DL} are maintained in the enabled state, the high-current pulse i_{DL} 223 through the laser diode D_{L} (and importantly, through the parasitic inductance L_{DL} of the laser diode D_{L}) diminishes to zero. Thereafter, both the bypass switch M_{BP} and the laser diode switch M_{DL} are disabled by de-asserted levels (e.g., from the controller 120) of the bypass switch gate driver signal GATE_{BP} 220 and the laser diode switch gate driver signal GATE_{DL} 221. Because the laser diode switch M_{DL} is not disabled until a current through the parasitic inductance L_{DL} of the laser diode D_{L} has diminished to zero, a high voltage spike advantageously does not develop at the anode of the laser diode D_{L} as there is no rapid change in current through the parasitic inductance L_{DL}. Because such high voltage spikes are advantageously mitigated, the laser diode switch M_{DL} does not need to be selected to withstand high voltages, thereby simplifying the design and reducing the cost of the pulsed laser diode drivers disclosed herein as compared to conventional solutions. Additionally, because such high voltage spikes are mitigated, the pulsed laser diode drivers disclosed herein do not require voltage snubbing circuits that are commonly used in conventional solutions, thereby further simplifying the design and reducing the cost of the pulsed laser diode drivers disclosed herein as compared to conventional solutions.

The high-current pulse i_{DL} 223 is a first and largest peak of the resonant waveform developed by reactive components of the pulsed laser diode driver circuit. These reactive components include the source capacitor C_{S}, the inductor L_{S}, the parasitic inductance L_{DL} of the laser diode D_{L}, and the bypass capacitor C_{BP}. In addition to the advantages described above, the bypass switch M_{BP} also reduces subsequent resonant waveform “ringing” of the resonant waveform after the high-current pulse i_{DL} 223 is generated. As shown in the plot 206, if a bypass switch gate driver signal GATE_{BP} 220′ is not asserted after a high-current pulse i_{DL} 223′ is generated, ringing occurs on the current i_{LS} 222′ through the inductor L_{S}, on the current i_{DL} 223′ through the laser diode D_{L}, and on the source voltage V_{S} 224′ at the source capacitor C_{S}. As shown, the high-current pulse i_{DL} 223 through the laser diode D_{L} corresponds to a peak (e.g., maximum, or local maximum, amplitude) current of a resonant waveform of current i_{DL} 223′ developed at the anode of the laser diode D_{L}.

As previously described, values of the source capacitor C_{S}, the inductor L_{S} and the bypass capacitor C_{BP} may be advantageously selected or “tuned” by a designer to meet desired performance criteria of the pulsed laser diode driver disclosed herein. For example, a capacitance value of the bypass capacitor C_{BP} may be selected based on a desired pulse width of the current i_{DL} through the laser diode D_{L}. The plot 207 shows the high-current pulse i_{DL} 223 generated when the capacitance of the bypass capacitor C_{BP} is equal to 1 nF, and a pulse 223″ generated when the capacitance of the bypass capacitor C_{BP} is equal to 4 nF. In use cases where a wider pulse, such as the pulse 223″, is desired, the source voltage V_{S} may be raised accordingly. Additionally, in some embodiments, the width of the de-asserted portion of the bypass switch gate driver signal GATE_{BP} 220 is widened to accommodate a wider pulse.

FIG. 3 illustrates a portion of an example switching sequence 300 for operation of the pulsed laser diode driver 101 shown in FIG. 1, in accordance with some embodiments, and as was described with reference to FIGS. 2A-D At a precharge step 301, the bypass switch M_{BP} and the laser diode switch M_{DL} are off (i.e., not conducting). During the precharge step 301, the source capacitor C_{S} is charged through the source resistor R_{S}. At a preflux step 302, the bypass switch M_{BP} and the laser diode switch M_{DL} are transitioned to an ON-state, thereby allowing the current i_{LS} to flow through the inductor L_{S} to store energy in the form of magnetic flux at the inductor L_{S}. Even though both of the switches (M_{DL}, M_{BP}) are in an ON-state at the preflux step 302, the bypass path through the bypass switch M_{BP} will carry all of the current i_{LS} because a bandgap voltage of the laser diode D_{L} needs to be overcome to allow current to flow through the laser diode D_{L}.

In some embodiments, the laser diode switch M_{DL} is transitioned to an ON-state after the bypass switch M_{BP} is transitioned to an ON-state. At a pulse generation step 303, the bypass switch M_{BP} is transitioned to an OFF-state while the laser diode switch M_{DL} is maintained in an ON-state, thereby generating the high-current pulse through the laser diode D_{L}. When the bypass switch M_{BP} is transitioned to the OFF-state, voltage at the anode of the laser diode D_{L} rises quickly until the bandgap voltage of the laser diode D_{L} is overcome and the laser diode D_{L} begins to conduct current. Because of a resonant circuit formed by the bypass capacitor C_{BP} and the parasitic inductance L_{DL} of the laser diode D_{L}, the voltage formed at the anode of the laser diode D_{L} will advantageously rise as high as necessary to overcome the bandgap voltage of the laser diode D_{L} and will generally be higher than the source voltage V_{S}.

At a discharge step 304, the bypass switch M_{BP} and the laser diode switch M_{DL} are maintained in an ON-state to drain charge stored at the source capacitor C_{S}, thereby reducing the current i_{DL} through the parasitic inductance L_{DL} to advantageously eliminate a high voltage spike at the anode of the laser diode D_{L} when the laser diode switch M_{DL} is transitioned to an OFF-state. At step 305, the bypass switch M_{BP} and the laser diode switch M_{DL} are transitioned to an OFF-state, thereby returning to the precharge state at step 301. Because the source voltage V_{S} at the source capacitor C_{S} is completely discharged at the end of the discharge step 304, there is very little current through the laser diode D_{L}. Thus, there is advantageously very little overshoot when the switches M_{DL} and M_{BP} are transitioned to the OFF-state at step 305, thereby preventing damage to the laser diode D_{L} and the switches M_{DL} and M_{BP}. The time interval of the overall pulse and bypass signals is selected, in some embodiments, such that the source capacitor C_{S} is fully discharged before the switches M_{DL} and M_{BP} are transitioned to the OFF-state at step 305.

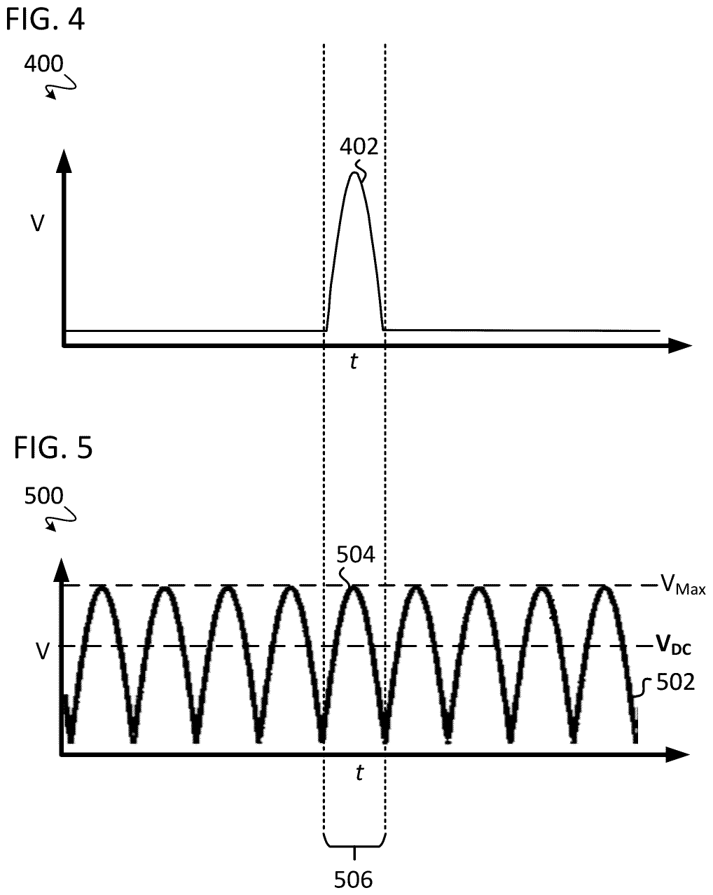

FIG. 4 shows a simplified plot 400 of signals related to operation of the pulsed laser diode driver 101 shown in FIG. 1, in accordance with some embodiments. The simplified plot 400 includes an isolated view of a voltage pulse 402 developed across the current sense resistance R_{Sense} by an ultra-short (Ins) high-current (100 A) pulse i_{DL} generated using a circuit similar to that shown in FIG. 1. In the example shown, the current sense resistance had a value of 10 mOhms. As described above, the high-current pulse i_{DL} is created by generating a damped harmonic oscillation at an anode of the laser diode D_{L} based on a resonant circuit that includes the inductor L_{S} and the bypass capacitor C_{BP}. The current sense resistance R_{Sense} can be either a discrete resistor or, advantageously, the RDSon of the same switch that is used to control pulse emission. In the example shown in FIG. 1, the current sense resistance R_{Sense} is an RDSon of a m fingers of the laser diode switch M_{DL}. As described below, during operation of the pulsed laser diode driver 101, the resistance RDSon of the laser diode switch M_{DL} may vary with temperature, gate drive, current, etc. However, as disclosed herein, the current pulse measurement circuit 140 is advantageously operable to compensate for changes in the resistance of RDSon to thereby provide a consistent and accurate current sense signal iₛₑₙₛₑ.

As mentioned above, accurately measuring a current amplitude of an ultra-short high-current pulse conventionally requires the use of high-speed comparators. However, such comparators may add undesirable complexity, size, and cost to a design. The current pulse measurement circuit 140 disclosed herein is advantageously operable to consistently and accurately measure the current amplitude of ultra-short high-current pulses without using high-speed comparators by determining a DC value of the high-current pulse and then converting that DC value to a corresponding peak value of the high-current pulse.

To illustrate, FIG. 5 shows a simplified plot 500 of a 100 MHz rectified sinusoid waveform 502. Also shown are dashed lines representing a peak voltage V_{Max} of the waveform 502, a DC value V_{DC} of the waveform 502, and vertical lines 506. As is known by one of ordinary skill in the art, the DC value V_{DC} of the waveform 502 is equal to about 63.7% of the peak voltage V_{Max} when integrating over a single cycle—e.g., a single pulse 504 of the waveform 502. Thus, if a DC value of a single high-current pulse is determined during the interval of time illustrated by the vertical lines 506, the peak thereof may subsequently be easily determined. However, when considering a single pulse, the DC value of the single high-current pulse must be determined such that the peak voltage V_{Max} is measured at the correct time. As described above, emission of the single high-current pulse is caused when the laser diode switch M_{DL} is enabled. Thus, determining the peak voltage V_{Max} of a single pulse may be advantageously synchronized with emission of the laser diode switch gate driver signal GATE_{DL}.

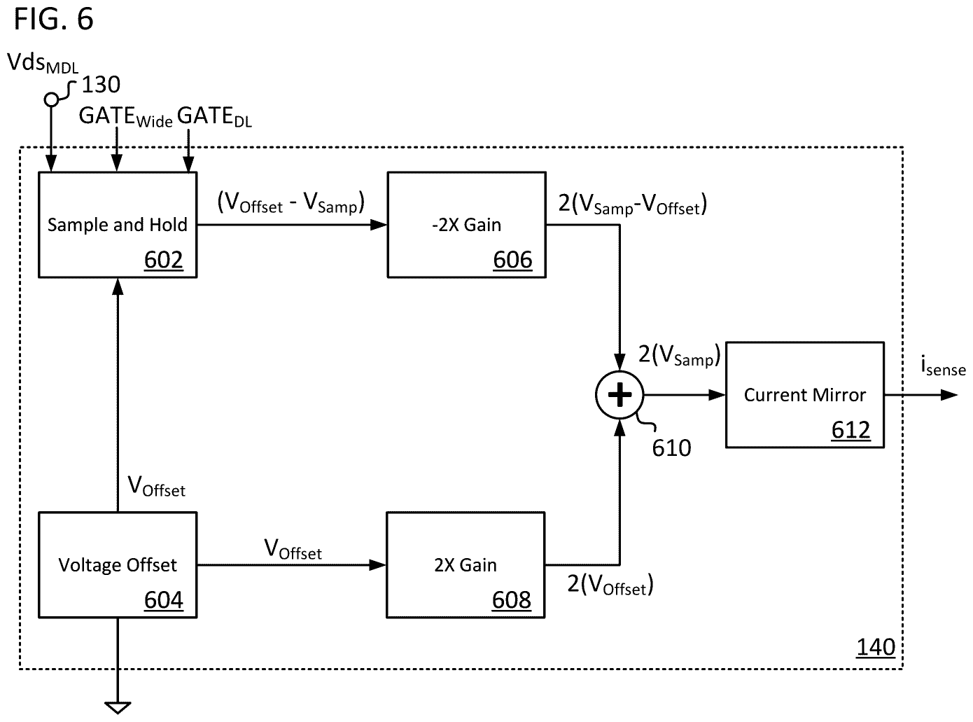

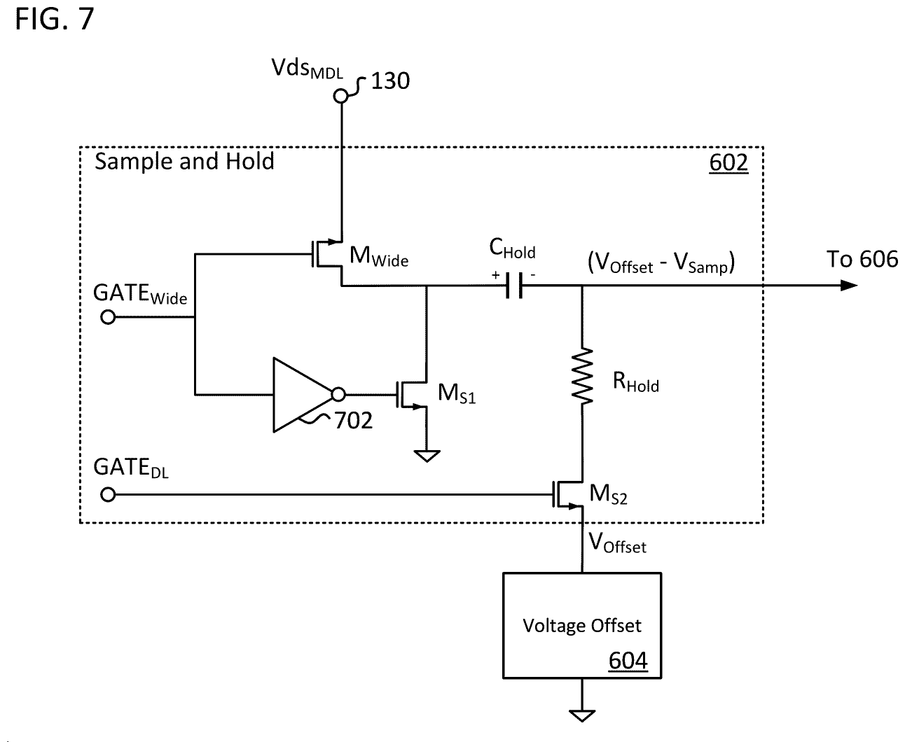

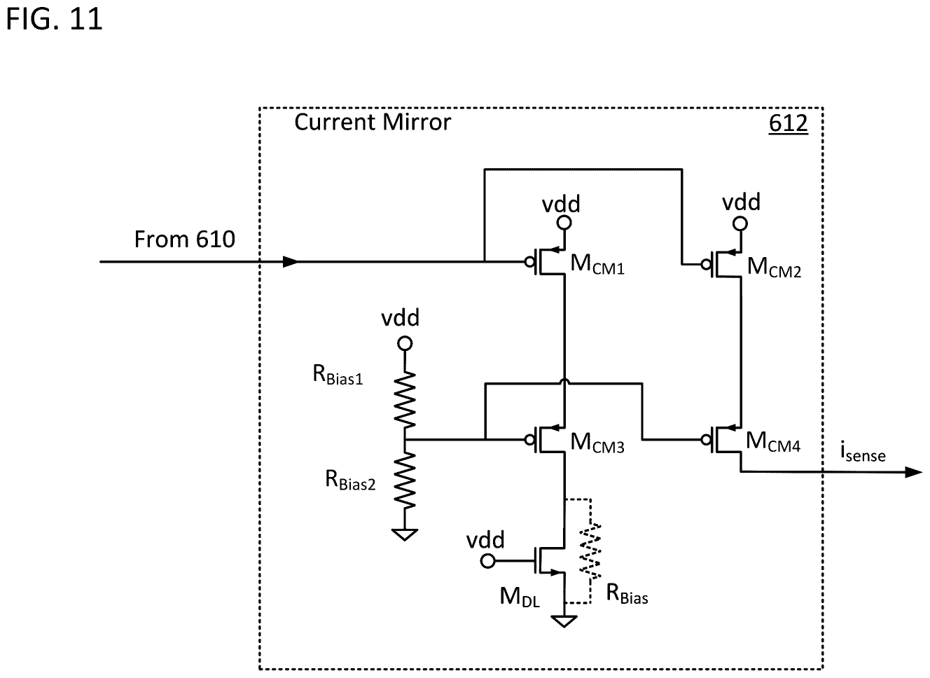

FIG. 6 is a simplified circuit schematic of the current pulse measurement circuit 140 of the pulsed laser diode driver 101 shown in FIG. 1, in accordance with some embodiments. As shown, the current pulse measurement circuit 140 generally includes a sample and hold circuit 602, a voltage offset generation circuit 604, a first signal amplifier circuit (“−2× Gain”) 606, a second signal amplifier circuit (“2× Gain”) 608, a signal summing amplifier circuit 610, and a current mirror circuit 612, connected as shown. Also shown is the node 130 and signals VdS_{MDL}, V_{Offset}, V_{Samp}, and iₛₑₙₛₑ. Details of the sample and hold circuit 602 and the current mirror circuit 612 are described below with reference to FIG. 7 and FIG. 11, respectively. In some embodiments, the first signal amplifier circuit 606 and the second signal amplifier circuit 608 are implemented using respective op-amp circuits. In some embodiments, the signal amplifiers 606 and 608 may be implemented using a single amplifier circuit.

The sample and hold circuit 602 is operable to sample and hold a DC sense voltage VdS_{MDL} amplitude generated as the high-current pulse i_{DL} passes through the sense resistance R_{Sense} shown in FIG. 1. The resultant sampled signal V_{Samp} is offset, by the current pulse measurement circuit 140, by a fixed voltage offset V_{Offset} that is generated by the voltage offset generation circuit 604 (e.g., using Vᵢₙ). In some embodiments, the voltage offset generation circuit 604 generates the fixed voltage offset Voffset using a resistor divider network (not shown). In other embodiments, the voltage offset generation circuit 604 generates the fixed voltage offset V_{Offset} using a voltage generator circuit such as a Digital to Analog Converter (DAC) circuit (not shown), or a low-dropout (LDO) voltage converter (not shown). The sample and hold circuit 602 provides an inverted value of the sampled voltage V_{Samp}, offset by the fixed voltage offset V_{Offset}—i.e., (V_{Offset}−V_{Samp}). As described below, the fixed voltage offset V_{Offset} advantageously enables the current pulse measurement circuit 140 to be implemented without the need for a negative voltage supply, thereby further reducing design complexity and cost as compared to a current pulse measurement circuit that requires a negative voltage supply.

The offset sampled voltage (V_{Offset}−V_{Samp}) is received at the first signal amplifier circuit 606, and the fixed voltage offset V_{Offset} is received at the second signal amplifier circuit 608. The first signal amplifier circuit 606 generates an inverted scaled version (e.g., −2×, −4×, −8×, etc.) of the offset sampled voltage (V_{Offset}−V_{Samp}). For example, if the first signal amplifier circuit 606 is configured to scale input signals by −2×, the output of the first signal amplifier circuit 606, re-written to account for the sign change, is 2(V_{Samp}−V_{Offset}). Similarly, the second signal amplifier circuit 608 generates a scaled version (e.g., 2×, 4×, 8×, etc.) of the fixed voltage offset V_{Offset}. For example, if the second signal amplifier circuit 608 scales input signals by 2×, the output of the second signal amplifier circuit 608 is 2(V_{Offset}). The outputs of the first signal amplifier circuit 606 and the second signal amplifier circuit 608 are summed by the signal summing circuit 810 to generate a scaled sampled voltage, 2(V_{Samp}). The scaled sampled voltage 2(V_{Samp}) is received by the current mirror circuit 612 which generates a current signal output iₛₑₙₛₑ that is representative of a peak current amplitude of the high-current pulse i_{DL} which passed through the laser diode D_{L} and the sense resistance R_{Sense}.

FIG. 7 is a simplified circuit schematic of the sample and hold circuit 602 of the current pulse measurement circuit 140 shown in FIG. 6, in accordance with some embodiments. As shown, the sample and hold circuit 602 generally includes a signal inverter circuit 702, a resistor R_{Hold}, an AC coupled signal hold capacitor C_{Hold}, a wide gating switch M_{Wide}, a switch M_{S1}, and a clamping switch M_{S2}, coupled as shown. Also shown are signals VdS_{MDL}, GATE_{Wide}, GATE_{DL}, V_{Offset}, and V_{Samp}. The wide gating signal GATE_{Wide} is generated by the controller 120, e.g., using a delay and timing circuit (not shown), such that the wide gating signal GATE_{Wide} is enabled slightly before the laser diode switch gate driver signal GATE_{DL} (a “narrow gating signal”) is enabled and is disabled slightly after the laser diode switch gate driver signal GATE_{DL} is disabled, thereby blocking signals to the sample and hold circuit 602 during portions of the laser diode driver switching cycle that are not of interest (e.g., all of the time leading up to, and following, pulse emission of the laser diode D_{L}).

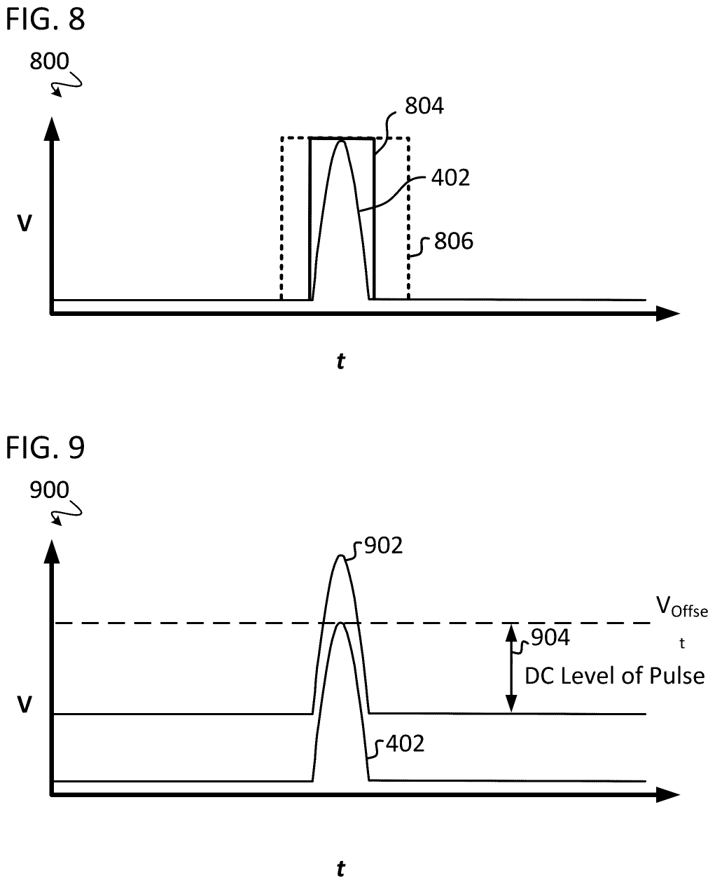

For example, FIG. 8 shows a simplified plot 800 of the voltage pulse 402 developed at the current sense resistance R_{Sense} by the ultra-short high-current pulse i_{DL} as described with reference to FIG. 4, in accordance with some embodiments. The plot 800 shows a narrow measurement window 804 that is generated by the controller 120 using the laser diode switch gate driver signal GATE_{DL} (i.e., a narrow gating signal), and a wide measurement window 806 that is generated by the controller 120 using the gating signal GATE_{Wide} (i.e., a wide gating signal), both of which are centered on the voltage pulse 402. The narrow measurement window 804 is generated based on the laser diode switch gate driver signal GATE_{DL} and therefore occurs at the same time, and with the same duration, as the laser diode switch gate driver signal GATE_{DL}. By comparison, the wide measurement window 806 is initiated by the optional controller 120 using the wide gating signal GATE_{Wide} before the diode switch gate driver signal GATE_{DL} is enabled and has a duration that is greater than that of the diode switch gate driver signal GATE_{DL}.

Returning attention to FIG. 7, during the time that the gating signal GATE_{Wide} is disabled, the sense voltage VdS_{MDL} developed at the sense resistance R_{Sense} is blocked by the wide gating switch M_{Wide} from passing through the signal hold capacitor C_{Hold}, and a positive terminal of the signal hold capacitor C_{Hold} (indicated by a ‘+’ designator) is coupled to ground. During the time that the laser diode switch gate driver signal GATE_{DL} is disabled, a negative terminal of the signal hold capacitor C_{Hold} (indicated by a ‘−’ designator) is held at a high impedance. As such, when both of the signals GATE_{Wide} and GATE_{DL} are disabled, a DC voltage level at the signal hold capacitor C_{Hold} is held at a constant value.

During the time that the gating signal GATE_{wide} is enabled, the sense voltage VdS_{MDL} developed at the sense resistance R_{Sense} is received at the signal hold capacitor C_{Hold} via the wide gating switch M_{Wide}. During the time that the laser diode switch gate driver signal GATE_{DL} is enabled, an AC component of a current developed based on the sense voltage VdS_{MDL} is able to pass through the signal hold capacitor C_{Hold}, the signal hold capacitor C_{Hold} being charged to the DC offset component (V_{Samp}) of that current. The negative terminal of the signal hold capacitor C_{Hold} is clamped, via the clamping switch M_{S2}, to the voltage offset V_{Offset} produced by the voltage offset generation circuit 604. As such, the DC voltage developed at the resistor R_{Hold} is equal to V_{Offset}−V_{Samp}.

Because the sampled voltage V_{Samp} is clamped to the offset voltage V_{Offset}, the first signal amplifier circuit 606 advantageously does not require a negative voltage supply to produce a voltage representative of the DC level of the sense voltage VdS_{MDL} developed at the sensing resistance. That is, if V_{Offset} were equal to 0 Volts, then the DC voltage developed at the resistor R_{Hold} would be equal to −V_{Samp}, thereby necessitating that the first signal amplifier circuit 606 have a negative voltage rail. Instead, as shown, in FIG. 9, the offset voltage V_{Offset} advantageously shifts a DC level of the sampled voltage V_{Samp} into a positive voltage regime.

To elaborate, FIG. 9 shows a simplified graph 900 of the voltage pulse 402 developed at the sensing resistance and a voltage-clamped representation 902 of the voltage pulse 402 developed at the sense resistance R_{Sense}. A DC level 904 of the voltage pulse 402 is equal to the difference between the voltage offset V_{Offset} and a voltage level of the voltage-clamped representation 902. As shown in FIG. 9, if V_{Offset} were equal to zero volts, the pulse 902 would attain negative voltage levels.

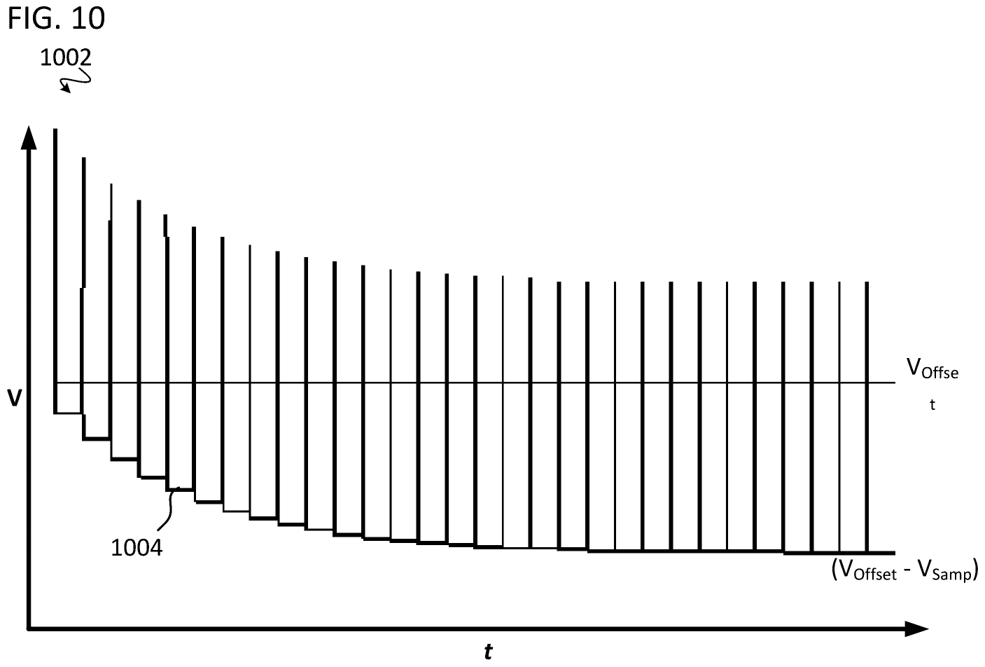

Each time that the gating signals GATE_{Wide} and GATE_{DL} are enabled, which corresponds to each pulse emission of the laser diode D_{L}, the voltage level at the AC-coupled signal hold capacitor C_{Hold} successively approaches the average DC level of the voltage pulse 402. For example, FIG. 10 shows a simplified graph 1002 of a DC voltage level 1004 (V_{Offset}−V_{Samp}) developed at the signal hold capacitor C_{Hold} (i.e., V_{Offset}−V_{Samp}) over time. As shown in FIG. 10, as time goes on, the voltage level (V_{Offset}−V_{Samp}) reaches a steady-state which accurately represents an average DC voltage level that is representative of voltage developed across the sense resistance R_{Sense} from each of the ultra-short high current pulses i_{DL}. Once a steady-state of the DC voltage level is reached, the DC voltage level will no longer change unless there is a change in the driving parameters that created the pulse, such as supply voltage, gate drive, temperature, current, etc. The DC voltage level, which corresponds to about 63.7% of the peak voltage across the current sense resistance R_{Sense}, is then further scaled by the current mirror circuit 612 to generate a current sense signal iₛₑₙₛₑ that is representative of the peak current amplitude of the ultra-fast current pulse i_{DL} through the laser diode D_{L}.

FIG. 11, is a simplified circuit schematic of the current mirror circuit 612 of the current pulse measurement circuit 140 shown in FIG. 6, in accordance with some embodiments. As shown, the current mirror circuit 612 generally includes a bias voltage generator circuit that includes resistors R_{Bias1} and R_{Bias2}, switches M_{CM1-4}, and a reference bias resistance R_{Bias} formed by the RDSon of N fingers of the laser diode switch M_{DL}. Because the reference bias resistance R_{Bias} is formed using N fingers of the laser diode switch M_{DL}, the current mirror circuit 612 advantageously tracks parametric changes of the laser diode switch M_{DL}, to provide a consistent ratio of the sense resistance R_{Sense} to the bias resistance R_{Bias} (i.e., a ratio of m sense resistance fingers to N bias resistance fingers) despite changes in temperature, gate drive, current, etc. As such, the current sense signal iₛₑₙₛₑ remains an accurate representation of a current through the sense resistance R_{Sense} across a wide range of operating conditions. Additionally, by choosing, at design time, a ratio of the m fingers of the laser diode switch M_{DL} used for the sense resistance R_{Sense} versus the N fingers of the laser diode switch M_{DL} used for the bias resistance R_{Bias}, a scale of the current sense signal may be advantageously selected. In some embodiments, the current sense signal iₛₑₙₛₑ is received at an external resistor (not shown) to convert the current sense signal iₛₑₙₛₑ into a voltage at the external resistor.

A second stage of the current mirror circuit 612 that includes the switches M_{CM2} and M_{CM4} additionally scales the current sense signal iₛₑₙₛₑ to produce a desired representation of the sensed current amplitude of i_{DL}. For example, in some embodiments, the ratio of fingers m to N of the laser diode switch M_{DL}, the scaling value of the second stage of the current mirror circuit 612, and/or the value of the external resistor (not shown) are selected such that each volt developed at the external resistor represents one amp of current through the current sense resistance Rₛₑₙₛₑ.

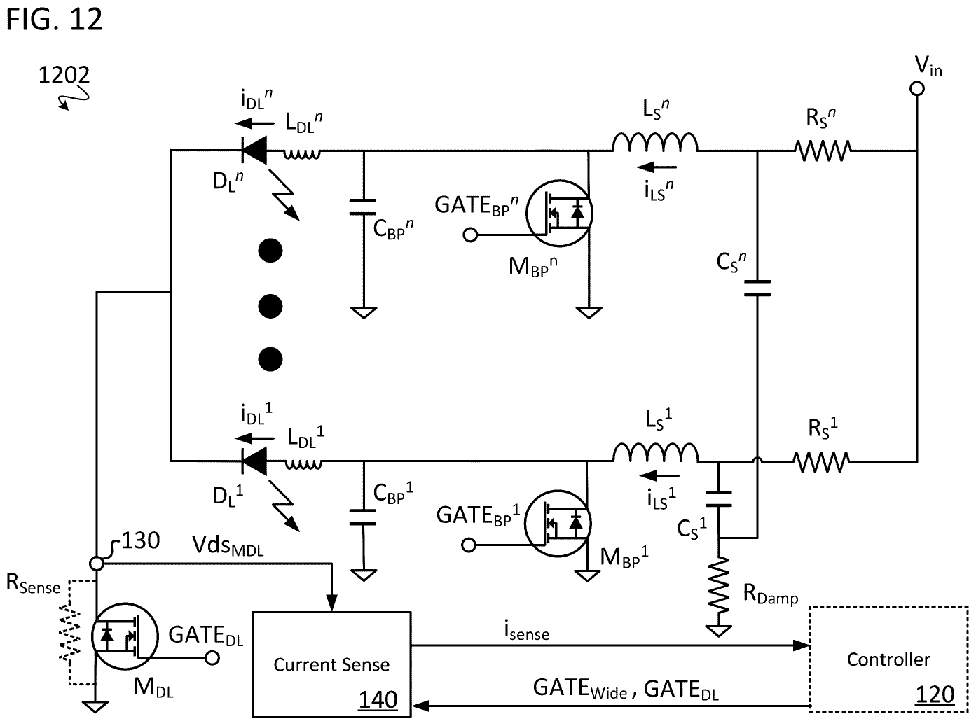

FIG. 12 is a simplified circuit schematic of a multi-channel pulsed laser diode driver 1202 of a second general topology that is configured for multi-channel, individual control of multiple laser diodes, in accordance with some embodiments. The multi-channel pulsed laser diode driver 1202 shown in FIG. 12 is configured to independently drive n laser diodes where n is a number ranging from two, to four (i.e., a quad pack), to 128 or more. The multi-channel pulsed laser diode driver 1202 is operable to cause a pulse to be emitted from any individual laser diode of the multi-channel pulsed laser diode driver 1202 in isolation, or combined with one or more other pulses emitted from other laser diodes of the multi-channel pulsed laser diode driver 1202. The multi-channel pulsed laser diode driver 1202 generally includes n source resistors R_{S}¹ through R_{S}ⁿ, n source capacitors C_{S}¹ through C_{S}ⁿ, an optional damping resistor R_{Damp}, n inductors L_{S}¹ through L_{S}ⁿ, n bypass switches M_{BP}¹ through M_{BP}ⁿ, n bypass capacitors C_{BP}¹ through C_{BP}ⁿ, n laser diodes D_{L}¹ through D_{L}ⁿ, and a laser diode switch M_{DL}, coupled as shown. Also shown is the controller 120 described above, the current sense resistance R_{Sense} and the current pulse measurement circuit 140 described above, respective parasitic inductances L_{DL}¹ through L_{DL}ⁿ of the laser diodes D_{L}¹ through D_{L}ⁿ, respective currents i_{LS}¹ through i_{LS}ⁿ of the inductors L_{S}¹ through L_{S}ⁿ, respective currents i_{DL}¹ through i_{DL}ⁿ of the laser diodes D_{L}¹ through D_{L}ⁿ, the DC input voltage Vᵢₙ, the wide gating signal GATE_{Wide}, and the node 130. The damping resistor R_{Damp} is used in some embodiments for current measurement purposes and can be omitted by connecting each of the source capacitors C_{S}¹ through C_{S}ⁿ to ground. In some embodiments, the bypass switches M_{BP}¹ through M_{BP}ⁿ and the laser diode switch M_{DL} are each N-type FET switches and advantageously do not require bootstrap circuitry to drive the respective gates of those switches because of their respective low-side configurations.

The source resistor R_{S}¹, the source capacitor C_{S}¹, the inductor L_{S}¹, the bypass switch M_{BP}¹, the bypass capacitor C_{BP}¹, and the laser diode D_{L1} are associated with a first channel of the multi-channel pulsed laser diode driver 1202. Similarly, the source resistor R_{S}ⁿ, the source capacitor C_{S}ⁿ, the inductor L_{S}ⁿ, the bypass switch M_{BP}ⁿ, the bypass capacitor C_{BP}ⁿ, and the laser diode D_{L}ⁿ are associated with an n^{th} channel of the multi-channel pulsed laser diode driver 1202, where n is a number greater than one (e.g., two, three, four, eight, 16, 32, 64, 128, etc.). By controlling (e.g., by the controller 120) respective switch timings (i.e., an on/off duration) of the bypass switches M_{BP}¹ through M_{BP}ⁿ in conjunction with controlling a switch timing of the laser diode switch M_{DL}, each of the laser diodes D_{L}¹ through D_{L}ⁿ is advantageously independently controlled. Operation of each channel of the multi-channel pulsed laser diode driver 1202 is similar to, or the same as, operation of the pulsed laser diode driver 101 described with reference to FIG. 1 and the switching sequence 300 shown in FIG. 3. Because each of the bypass switches M_{BP}¹ through M_{BP}ⁿ and the laser diode switch M_{DL} are configured as low-side switches (i.e., a source node of each aforementioned switch is directly electrically connected to ground), a gate control signal of those switches does not need to be level-shifted by bootstrap circuitry, thereby advantageously simplifying the design and reducing the cost of the multi-channel pulsed laser diode driver 1202 as compared to a laser diode driver circuit that requires bootstrap circuitry.

In some embodiments, the DC input voltage Vᵢₙ is advantageously provided by an adjustable voltage supply (i.e., a digital-to-analog converter (DAC)) (not shown). In some embodiments, an output voltage level of the adjustable voltage supply is set using the controller 120. Use of an adjustable voltage supply, such as a DAC, to provide the DC input voltage Vᵢₙ to the pulsed laser diode driver circuits disclosed herein is possible because of the advantageously low input voltage requirements for such embodiments. In some embodiments, the adjustable voltage supply is clocked such that the adjustable voltage supply charges the source capacitor(s) C_{S} described herein only during a first portion of a clock period (e.g., a positive portion). As such, the value of the DC input voltage Vᵢₙ and a current amplitude of the high-current pulse delivered to the laser diode(s) disclosed herein may be advantageously varied between consecutive high-current pulses through the laser diode(s).

As described above, the current pulse measurement circuit 140 is advantageously operable to generate a current sense signal iₛₑₙₛₑ that is representative of a peak current amplitude through the switch M_{DL}. Because each of the laser diodes D_{L}¹⁻ⁿ is independently controlled by the multi-channel pulsed laser diode driver 1202, the current sense signal iₛₑₙₛₑ may be indicative of the peak current amplitude through one, two, four, or any number n of the laser diodes D_{L}¹⁻ⁿ.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A pulsed laser diode driver comprising:
a first inductor having a first terminal and a second terminal, the first terminal of the first inductor being configured to receive a first source voltage, the first source voltage being based on a DC input voltage;
a first source capacitor having a first terminal directly electrically connected to the first terminal of the first inductor to provide the first source voltage and a second terminal electrically coupled to ground;
a first bypass switch having a drain node that is directly electrically connected to the second terminal of the first inductor and a source node that is directly electrically connected to ground;
a first bypass capacitor having a first terminal directly electrically connected to the drain node of the first bypass switch;
a first laser diode having an anode and a cathode, the anode of the first laser diode being directly electrically connected to the second terminal of the first inductor and to the drain node of the first bypass switch;
a laser diode switch having a drain node that is directly electrically connected to the cathode of the first laser diode and a source node that is directly electrically connected to ground; and
a current pulse measurement circuit configured to receive a sense voltage developed at a sense resistance and to generate, based on the sense voltage, a current sense signal that corresponds to a peak current amplitude of a high-current pulse through the first laser diode;
wherein:
the laser diode switch and the first bypass switch are configured to control a current flow through the first inductor to produce the high-current pulse through the first laser diode, the high-current pulse corresponding to a peak current of a resonant waveform developed at the anode of the first laser diode.

2. The pulsed laser diode driver of claim 1, wherein the current pulse measurement circuit comprises:
a voltage offset circuit to generate an offset voltage;
a sample and hold circuit that receives the sense voltage and the offset voltage and generates a sampled signal therefrom;
a first voltage amplifier circuit that receives the sampled signal and generates a first scaled sampled signal therefrom;
a second voltage amplifier circuit that receives the offset voltage and generates a scaled offset voltage signal therefrom;
a voltage adder circuit that adds the first scaled sampled signal and the scaled offset voltage signal and generates a second scaled sampled signal therefrom; and
a current mirror circuit that receives the second scaled sampled signal and generates the current sense signal therefrom.

3. The pulsed laser diode driver of claim 2, wherein the sample and hold circuit comprises:
a signal hold capacitor that receives the sense voltage at a first terminal only when the laser diode switch is enabled.

4. The pulsed laser diode driver of claim 3, wherein the sample and hold circuit further comprises:
a wide gating switch that controls when the sense voltage is received at the first terminal of the signal hold capacitor based on a wide gating signal that is centered on the high-current pulse; and
a clamping switch that clamps a voltage at a second terminal of the signal hold capacitor to the offset voltage based on a narrow gating signal that is centered on the high-current pulse and is of a shorter duration than the wide gating signal.

5. The pulsed laser diode driver of claim 2, wherein:
a resistance of the sense resistance corresponds to a drain-source on-resistance of a first portion of fingers of the laser diode switch.

6. The pulsed laser diode driver of claim 5, wherein the current mirror circuit comprises:
a bias resistance having a resistance that corresponds to the drain-source on-resistance of a second portion of fingers of the laser diode switch, the current sense signal being generated based on the bias resistance.

7. The pulsed laser diode driver of claim 1, further comprising:
a second inductor having a first terminal and a second terminal, the first terminal of the second inductor being configured to receive the first source voltage;
a second source capacitor having a first terminal directly electrically connected to the first terminal of the second inductor to provide the first source voltage and a second terminal electrically coupled to ground;
a second bypass switch having a drain node that is directly electrically connected to the second terminal of the second inductor and a source node that is directly electrically connected to ground;
a second bypass capacitor having a first terminal directly electrically connected to the drain node of the second bypass switch; and
a second laser diode having an anode and a cathode, the anode of the second laser diode being directly electrically connected to the second terminal of the second inductor and to the drain node of the second bypass switch, the drain node of the laser diode switch being directly electrically connected to the cathode of the second laser diode;
wherein:
the current pulse measurement circuit is configured to receive the sense voltage developed at the sense resistance that is based on a second high-current pulse through one or both of the first laser diode and the second laser diode, and to generate, based on the sense voltage, a second current sense signal that corresponds to a peak current amplitude of the second high-current pulse; and
the laser diode switch, the first bypass switch, and the second bypass switch are configured to control a current flow through one or both of the first inductor and the second inductor to produce the second high-current pulse through one or both of the first laser diode and the second laser diode.

8. A pulsed laser diode driver comprising:
a laser diode having an anode and a cathode;
a laser diode switch having a drain node that is directly electrically connected to the cathode of the laser diode and a source node that is directly electrically connected to ground; and
a current pulse measurement circuit configured to receive a sense voltage, developed at a sense resistance, that is based on a high-current pulse through the laser diode, and to generate, based on the sense voltage, a current sense signal that corresponds to a peak current amplitude of the high-current pulse;
wherein:
a resistance of the sense resistance corresponds to a drain-source on-resistance of a first portion of fingers of the laser diode switch.

9. The pulsed laser diode driver of claim 8, wherein the current pulse measurement circuit comprises:
a voltage offset circuit to generate an offset voltage;
a sample and hold circuit that receives the sense voltage and the offset voltage and generates a sampled signal therefrom;
a first voltage amplifier circuit that receives the sampled signal and generates a first scaled sampled signal therefrom;
a second voltage amplifier circuit that receives the offset voltage and generates a scaled offset voltage signal therefrom;
a voltage adder circuit that adds the first scaled sampled signal and the scaled offset voltage signal and generates a second scaled sampled signal therefrom; and
a current mirror circuit that receives the second scaled sampled signal and generates the current sense signal therefrom.

10. The pulsed laser diode driver of claim 9, wherein the sample and hold circuit comprises:
a signal hold capacitor that receives the sense voltage at a first terminal only when the laser diode switch is enabled.

11. The pulsed laser diode driver of claim 10, wherein the sample and hold circuit further comprises:
a wide gating switch that controls when the sense voltage is received at the first terminal of the signal hold capacitor based on a wide gating signal that is centered on the high-current pulse; and
a clamping switch that clamps a voltage at a second terminal of the signal hold capacitor to the offset voltage based on a narrow gating signal that is centered on the high-current pulse and is of a shorter duration than the wide gating signal.

12. The pulsed laser diode driver of claim 11, wherein the current mirror circuit comprises:
a bias resistance having a resistance that corresponds to the drain-source on-resistance of a second portion of fingers of the laser diode switch, the current sense signal being generated based on the bias resistance.

13. A current pulse measurement circuit, comprising:
a voltage offset circuit to generate an offset voltage;
a sample and hold circuit that receives i) a sense voltage developed at a sense resistance by a high-current pulse, and ii) the offset voltage, and generates a sampled signal therefrom;
a first voltage amplifier circuit that receives the sampled signal and generates a first scaled sampled signal therefrom;
a second voltage amplifier circuit that receives the offset voltage and generates a scaled offset voltage signal therefrom;
a voltage adder circuit that adds the first scaled sampled signal and the scaled offset voltage signal and generates a second scaled sampled signal therefrom; and
a current mirror circuit that receives the second scaled sampled signal and generates a current sense signal therefrom, the current sense signal corresponding to a peak current amplitude of the high-current pulse.

14. The current pulse measurement circuit of claim 13, wherein the sample and hold circuit comprises:
a signal hold capacitor that receives the sense voltage at a first terminal only when the high-current pulse is issued.

15. The current pulse measurement circuit of claim 14, wherein the sample and hold circuit further comprises:
a wide gating switch that controls when the sense voltage is received at the first terminal of the signal hold capacitor based on a wide gating signal that is centered on the high-current pulse; and
a clamping switch that clamps a voltage at a second terminal of the signal hold capacitor to the offset voltage based on a narrow gating signal that is centered on the high-current pulse and is of a shorter duration than the wide gating signal.

16. The current pulse measurement circuit of claim 13, wherein:
a resistance of the sense resistance corresponds to a drain-source on-resistance of a first portion of fingers of a switch that controls emission of the high-current pulse.

17. The current pulse measurement circuit of claim 16, wherein the current mirror circuit comprises:
a bias resistance having a resistance that corresponds to the drain-source on-resistance of a second portion of fingers of the switch, the current sense signal being generated based on the bias resistance.
